(19) United States
(12) Patent Application Publication
(10) Pub. No.: US 2012/0075129 A1
(43) Pub. Date: Mar. 29, 2012

(54) CALIBRATION OF IMPAIRMENTS IN A MULTICHANNEL TIME-INTERLEAVED ADC

(75) Inventor: Sunder S. Kidambi, Austin, TX (US)

(73) Assignee: Intersil America, Inc., Milpitas, CA (US)

(21) Appl. No.: 13/077,471

(22) Filed: Mar. 31, 2011

Related U.S. Application Data
(60) Provisional application No. 61/377,756, filed on Aug. 27, 2010.

(51) Int. Cl. H03M 1/06

(52) U.S. Cl. 341/118

(57) ABSTRACT

Techniques for correcting component mismatches in an M-channel time-interleaved Analog to Digital Converter (ADC). A number, M, of clock signals drive a corresponding number of main ADC elements with a selected plurality of different clock phases. Each of the ADCs has at least one of an offset correction input, a gain correction input, or a phase correction input. The M digital values output by the ADCs are interleaved to form a digital representation of the input signal. Also provided is a reference ADC that outputs reference digital values in response to at least one of the M clock signals at a time. The output of the reference ADC is compared and/or combined with the output from a selected one of the main ADCs to provide an estimate of offset, gain or phase. The error is accumulated to determine a corresponding correction of offset, gain or phase which is then fed back to the respective input of the corresponding main ADC.

### CROSS REFERENCE TO RELATED APPLICATIONS

This application is related to U.S. patent application Ser. No. 12/691,449, filed on Jan. 21, 2010 (Attorney Docket No.: 3575.1049-001), and claims the benefit of U.S. Provisional Application No. 61/377,756, filed on Aug. 27, 2010. The entire teachings of the above applications are incorporated herein by reference.

### BACKGROUND

An efficient way of providing very high sample rates, rates that cannot be provided by a single Analog-to-Digital Converter (ADC), is to use a parallel connection of slower ADCs operating in a time-interleaved fashion. Such a so-called M-channel time-interleaved ADC (MCTIADC) comprises M ADCs, each operating at a sample rate that is 1/M of the overall system sample rate. In the absence of any impairments or mismatch errors between the ADCs, i.e., assuming all the ADCs are either ideal or have exactly the same characteristics, the output samples appear at equally spaced intervals in a manner that creates a seamless image of a single ADC operating at the system sample frequency.

In practice, however, there are component mismatches between the different ADCs that severely degrade the performance of an MCTIADC system. The commonly occurring mismatches are offset, gain and sample instants. In other words, the offsets and gains of all the ADCs are not the same and the ADCs do not sample at uniform sample instants of the system sample frequency. These mismatches give rise to unnecessary frequency tones or spurs in the spectrum of the signal that significantly reduce the performance of the MCTIADC system.

A typical variation of Signal-to-Noise ratio (SNR) is shown in FIG. 1 wherein a tone is swept from a low frequency to almost half the sample rate of a simulated MCTIADC system for various mismatch errors. As can be seen from the figure, the performance of the four-channel ADC is severely hampered due to these errors. Hence, it becomes imperative to estimate and correct these errors to improve the performance of the MCTIADC system.

### SUMMARY

An extra ADC, called the reference ADC, can be used to minimize the effects of offset, gain and sample-time mismatches in an MCTIADC by appropriately estimating and correcting these errors in an adaptive manner. In addition, the adaptive method can be used in a blind mode wherein the use of any particular calibration signal is circumvented. In other words, the input signal itself serves as the calibrating signal to estimate and correct the mismatch errors.

More particularly, in a preferred embodiment, the estimation and correction of offset, gain and timing errors in an M-channel time-interleaved Analog-to-Digital Converter (MCTIADC) is accomplished by using an extra ADC used as a reference ADC. For practical purposes in this embodiment it is assumed that the wordlength of the extra ADC is less than or equal to that of the ADCs in the MCTIADC system.

The concept is based on the model shown in FIG. 2. There are M ADCs, each operating at 1/Mth the sample rate of the MCTIADC system sample frequency. There is a single reference ADC (ADCᵣ) with a wordlength equal to (R≦N) where N is the wordlength of the ADCs in the MCTIADC. The input to any ADCₖ, where k=1, 2, . . . , M, that is being calibrated is also connected to ADCᵣ. In this way, the estimation and correction of the impairments of ADCₖ is performed with respect to the impairments of ADCᵣ.

In order to obtain the offset error in each ADCₖ, the signal that passes through ADCₖ is also passed through ADCᵣ. A total of Nₒ samples is averaged (or summed) from the outputs of both ADCₖ and ADCᵣ. Call the sum or average of the signals from ADCₖ as Xₖ and the sum or average of the signals from ADCᵣ as Xᵣ. The sign of the offset error, i.e., sign (Xᵣ−Xₖ), is used to drive an adaptive algorithm to minimize this error such that the offset value of ADCₖ is as close to that of ADCᵣ. This procedure is repeated for each k where k=1, 2, . . . , M. Thus, the offset errors in all the ADCs in the MCTIADC system will be minimized with respect to that of ADCᵣ.

For estimating the gain error in each ADCₖ, the same configuration as mentioned above is adopted. The outputs of both ADCₖ and ADCᵣ are squared and an average (or sum) of N_{g} samples is obtained. Let the sum or average of the squared values of the signals from ADCₖ be Yₖ and that from ADCᵣ be Yᵣ. The sign of the gain error, i.e., sign (Yᵣ−Yₖ), is used to drive an adaptive algorithm to minimize this error such that the gain of ADCₖ is as close to that of ADCᵣ. This procedure is repeated for each k where k=1, 2, . . . , M. Thus, the gain errors in all the ADCs in the MCTIADC system will be minimized with respect to the gain error of ADCᵣ.

In order to obtain the sample-time error in each ADCₖ, a correlation between the outputs from ADCₖ and ADCᵣ over Nₚ samples is first obtained. An adaptive algorithm based on the slope of this correlation is then used to drive the sampling error between ADCᵣ and ADCₖ to a minimum. Again, this procedure is repeated for each k where k=1, 2, . . . , M. Thus, the sample-time errors in all the ADCs in the MCTIADC system will be minimized with respect to the sample-time error of ADCᵣ.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 illustrates Signal to Noise Ratio (SNR) variation with input frequency of a typical prior art four-channel Time-Interleaved Analog-to-Digital Converter for various mismatch errors.

FIG. 2 is a block diagram level model of M-channel Time-interleaved ADC using an extra ADC as reference according to one embodiment.

FIG. 3 illustrates a spectrum of a single tone signal with offset mismatch error before correction in a four-channel time-interleaved ADC.

FIG. 4A is a schematic illustrating how an offset error is estimated.

FIG. 4B is a schematic representing the recursive structure for effecting the offset correction.

FIG. 5 illustrates a spectrum of a single tone signal with offset mismatch error after correction in a four-channel time-interleaved ADC.

FIG. 6 illustrates a spectrum of a single tone signal with gain mismatch error before correction in a four-channel time-interleaved ADC.

FIG. 7A is a schematic illustrating how gain error is estimated.

FIG. 7B is a schematic representing the recursive structure for effecting the gain correction.

FIG. 8 illustrates a spectrum of a single tone signal with gain mismatch error after correction in a four-channel time-interleaved ADC.

FIG. 9 illustrates a spectrum of a single tone signal with phase mismatch error before correction in a four-channel time-interleaved ADC.

FIG. 10A is a schematic illustrating how phase error is estimated.

FIG. 10B is a schematic representing the recursive structure for effecting the phase correction.

FIG. 11 illustrates a spectrum of a single tone signal with phase mismatch error after correction in a four-channel time-interleaved ADC.

FIG. 12 illustrates a spectrum of a single tone signal with offset, gain and phase mismatch errors before correction in a four-channel time-interleaved ADC.

FIG. 13 illustrates a spectrum of a single tone signal with offset, gain and phase mismatch error after correction in a four-channel time-interleaved ADC.

FIG. 14 illustrates a spectrum of a wide-band signal with offset, gain and phase mismatch errors before correction in a four-channel time-interleaved ADC.

FIG. 15 illustrates a spectrum of a wide-band signal with offset, gain and phase mismatch error after correction in a four-channel time-interleaved ADC

FIG. 16 is a high level diagram of a digital receiver that may use the ADC System.

### DETAILED DESCRIPTION OF A PREFERRED EMBODIMENT

A description of example embodiments follows. While the invention is defined solely by the claims presented at the end of this document and therefore may be susceptible to embodiment in different forms, there is shown in the drawings, and will be described herein in detail, one or more specific embodiments, with the understanding that the present disclosure is to be considered but one exemplification of the principles of the invention. It is also to be understood that there is no intent to limit the invention to that which is specifically illustrated and described herein. Therefore, any references to the “invention” which may occur in this document are to be interpreted only as a reference to one particular example embodiment of but one aspect of the invention(s) claimed.

In preferred embodiments, estimation and correction of offset, gain and/or sample is timing or phase mismatch errors is provided in an M-channel Time-Interleaved Analog-to-Digital (MCTIADC) system. Here, the estimation is done in the digital domain while the correction is performed in the analog domain. The various errors are estimated by performing signal processing operations on the outputs of all the ADCs, including a reference ADC, viz., ADCᵣ, while corresponding correction values are communicated to all the ADCs through Digital-to-Analog Converters (DACs). The DACs provide appropriate voltages or currents and control either directly or indirectly the correction of each of the ADCs for the different mismatch errors.

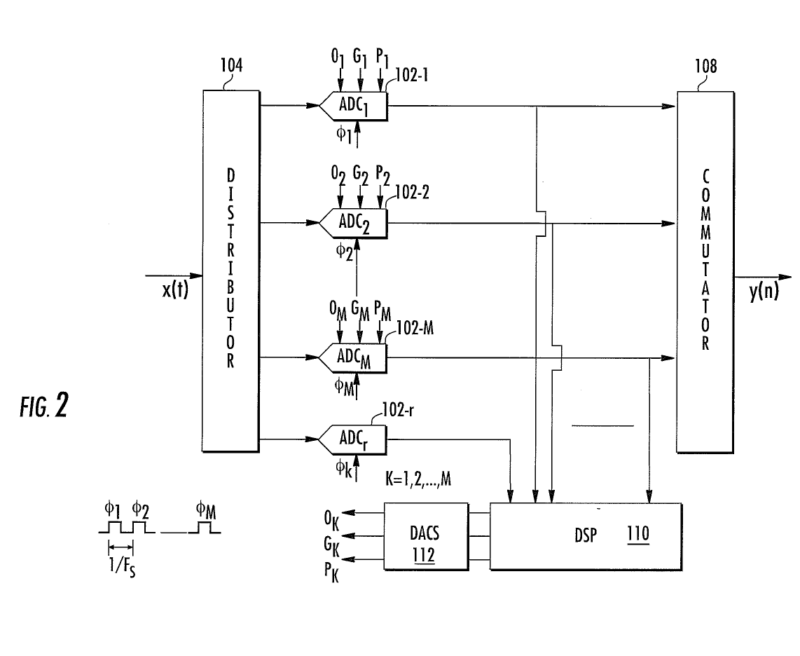

FIG. 2 shows a high level schematic of an MCTIADC system 100 wherein each “main” ADC 102-1, 102-2, . . . , 102-M is operating at F_{S}/M sampling rate and clocked at the appropriate phase Φ. The different phases applied to the different ADCs depend on the number, M, of ADCs 102. In a preferred implementation the increment between phases applied to each ADC is 2π/M. For example, if M=4 and the phase applied to a first ADC 102-1 is Ω, then the phases applied to ADC 102-2, 102-3 and 102-4 respectively are Ω+90, Ω+180, and Ω+270 degrees.

The clocking operation is controlled by a distributor circuit 104 which cycles the input signal x(t) through all the ADCs 102 in the MCTIADC system. The input to a chosen one of the “main” ADCs 102, say ADCₖ, (102-k) is also input to the “reference” ADC 102-r, i.e, ADCᵣ. The outputs from ADCₖ 102-k and ADCᵣ 102-r are used to estimate and correct offset, gain and sample-time mismatches of ADCₖ. The commutator 108 operates at the sample rate F_{S} and cycles through the output of every ADC 102-1, 102-2, . . . 102-k, . . . , 102-M to provide the output y(n) at F_{S}. As can be noted, the commutator 108 performs the opposite function of the distributor 104. Outputs from each ADC 102-1, 102-2, . . . , 102-k, . . . , 102-M, as well as the output from the reference ADC 102-r, are input to a digital signal processor (DSP) 110 in an appropriate manner. The DSP 110 performs the estimation of all the errors and provides signals corresponding to offset, is gain, and phase correction, represented by, Oₖ, Gₖ, and Pₖ that are then fed, respectively, to all the ADCs 102-1, 102-2, . . . , 102-k, . . . , 102-M. These correction values are forwarded to the ADCs though a set of digital to analog connectors (DACs) 112. Below we will describe the estimation of offset, gain, and phase mismatch errors by the DSP 110 using the outputs of each ADC, in conjunction with the output of the reference ADC, and their correction using adaptive algorithms that are performed within the DSP. There is typically a DAC 112 associated with each of the Oₖ, Gₖ and Pₖ correction inputs, for k=1 to m (e.g., there are typically 3 times M DACs 112 in total).

### Offset Correction

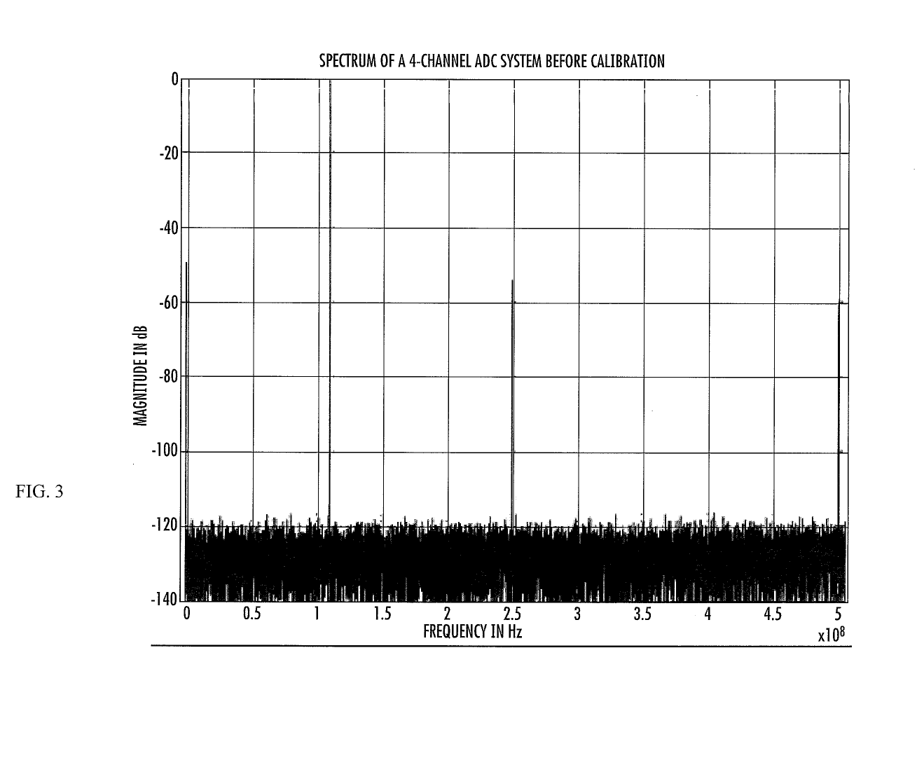

Due to the different offset values of the ADCs 102, offset spurs show up at kF_{S}/M frequencies. FIG. 3 shows the spectrum resulting from a simulation of a 110 MHz tone in a four-channel time-interleaved ADC system sampling at 1 GHz where the offset spurs appear at DC, 250 MHz and 500 MHz. As mentioned earlier, the offset spurs occur at multiples of the sample frequency of each ADC, i.e., multiples of 250 MHz, in this case. In order to minimize the amplitude of these spurs, the offsets of each ADC must be determined. The process involved in obtaining the offset mismatch error of each ADC is as follows. The input to a selected ADCₖ is also input to the reference ADC 102-r, i.e., ADCᵣ. The output from both these ADCs (102-k, 102-r) will be different due to different offsets of these two ADCs. At this point it must be mentioned that it is not necessary to reduce the offsets of all the ADCs 102 in the MCTIADC system to zero. It is only important to minimize the difference between the offset of each ADC 102-1, 102-2, . . . , 102-M in the MCTIADC system with respect to the offset of the reference ADC 102-r. In this way, all the ADCs will approximately have the same offset after correction.

Please note that the following discussion details how the various correction values are derived, and uses the pronoun “we” as is typical in discussing mathematical derivations in the plural first person. However, the use of the pronoun “we” herein is not meant to imply that there is more than one inventor of this particular patent.

Towards estimating the offset error of each ADC, we define the average value of the output of ADCₖ as

$${X}_{k} = \frac{1}{{N}_{o}} {\sum }_{n = 0}^{{N}_{o} - 1} {x}_{k} ( n ) \qquad ( 1 )$$

where xₖ(n) represents the samples from ADCₖ, and Nₒ is the number of samples collected to obtain the average Xₖ and k=1, 2, . . . M. The signal input to ADCₖ is also input to ADCᵣ and consequently we define the average value of the output of ADCᵣ as

$${X}_{r} = \frac{1}{{N}_{o}} {\sum }_{n = 0}^{{N}_{o} - 1} {x}_{R} ( n ) \qquad ( 2 )$$

We define an offset error for ADCₖ as

Eₖ^{offset}=Xᵣ−Xₖ (3)

for k=1, 2, . . . M.

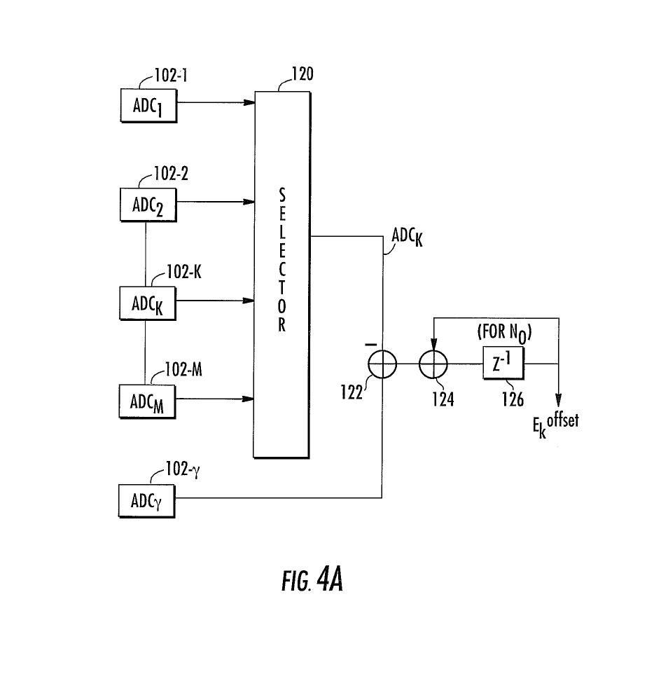

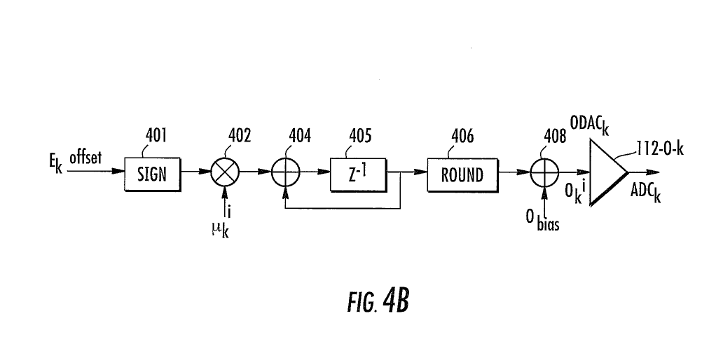

Such an offset error may be estimated by the circuit shown in FIG. 4A. A selector 120 chooses which one of the M ADC outputs is ADCₖ at any point in time. The selected ADCₖ is then subtracted 122 from ADCᵣ 102-r to obtain a difference. The difference is then accumulated by summer 124 and delay 126 over Nₒ samples to obtain Eₖ^{offset}. The accumulation is then reset by other circuitry (not shown) to obtain the next estimate of Eₖ^{offset}.

It should be noted that the division by Nₒ operation specified in the above equations and not shown in FIG. 4A is not necessary. This is because, as will be understood, it is really only the sign of the result that is used for the correction.

We now provide an adaptive algorithm to correct the offset error in each ADCₖ based on Eₖ^{offset}, for k=1, 2, . . . M. One implementation of the algorithm is shown in FIG. 4B.

By way of introduction, let ODACₖ be the DAC 112-O-k (FIG. 2) that provides the offset correction to ADCₖ. Let R_{O} be the range of ODACₖ. For example, for an 8-bit ODACₖ, R_{O}=2⁸=256. A step size that controls the convergence of the adaptive algorithm is denoted by μₖⁱ for ADCₖ at the ith iteration. The value of μₖⁱ is constrained to be in the range [μₖ^{offsetmin}, μₖ^{offsetmax}]. Let Oₖⁱ be the value input to the ODACₖ. For example, for an 8-bit ODACₖ, the values of Oₖⁱ can vary between [−128, 127] or between [0, 255]. The constant O_{bias} is a value that allows the correction to be done with respect to a certain bias. For instance, O_{bias}=R_{O}/2=128 when the input to the ODACₖ lies in the range [0, 255]. On the other hand when the range of the ODACₖ input values is in [−128, 127], O_{bias} can assume a value of zero. Let aₖⁱ denote a variable that provides correction to the ODACₖ input Oₖⁱ associated with ADCₖ at the ith iteration. We can now write the adaptive algorithm for offset correction as

$$\begin{matrix}{O}_{k}^{i} = {O}_{bias} + round ( {α}_{k}^{i} ) & ( 4 ) \\ {α}_{k}^{i + 1} = {α}_{k}^{i} + sign ( {E}_{k}^{offset} ) {μ}_{k}^{i} & ( 5 ) \\ {μ}_{k}^{i + 1} = max ( \frac{{μ}_{k}^{i}}{2} , {μ}_{k}^{offsetmin} ) for i = {r}_{k} & ( 6 )\end{matrix}$$

where aₖ⁰=0, μₖ⁰=μₖ^{offsetmax}, and rₖ is any arbitrary positive number. The convergence can be controlled by μₖⁱ by changing its value at every rₖth iteration.

In FIG. 4B, a schematic for adaptive algorithm performing offset correction is depicted. The sign 401 of each Eₖ^{offset} is multiplied 402 by the adaptation step-size and accumulated by summer 404 and delay 405. The accumulated value in each iteration is rounded 406 to the nearest integer value and added 408 to the offset bias, O_{bias}, to provide the offset correction value Oₖⁱ to the ODACₖ. The output from ODACₖ 112-o-k directly or indirectly controls the offset setting on ADCₖ, as depicted in FIG. 2. Such an adaptive process converges to an optimal value that minimizes the offset in ADCₖ with respect to that in ADCᵣ.

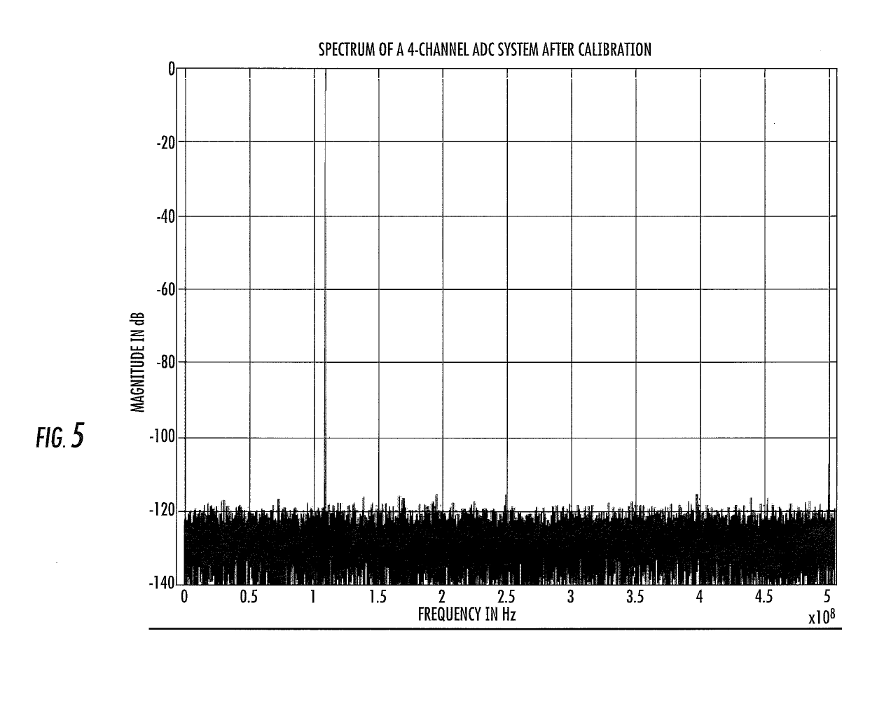

FIG. 5 shows the spectrum of the simulated tone mentioned in FIG. 3 after correction. As can be seen from the figure, the offset spurs at 250 MHz and 500 MHz are significantly reduced. In this simulation, it must be mentioned that the word length of each ADCₖ is 14 bits while that of ADCᵣ is 10 bits.

### Gain Correction

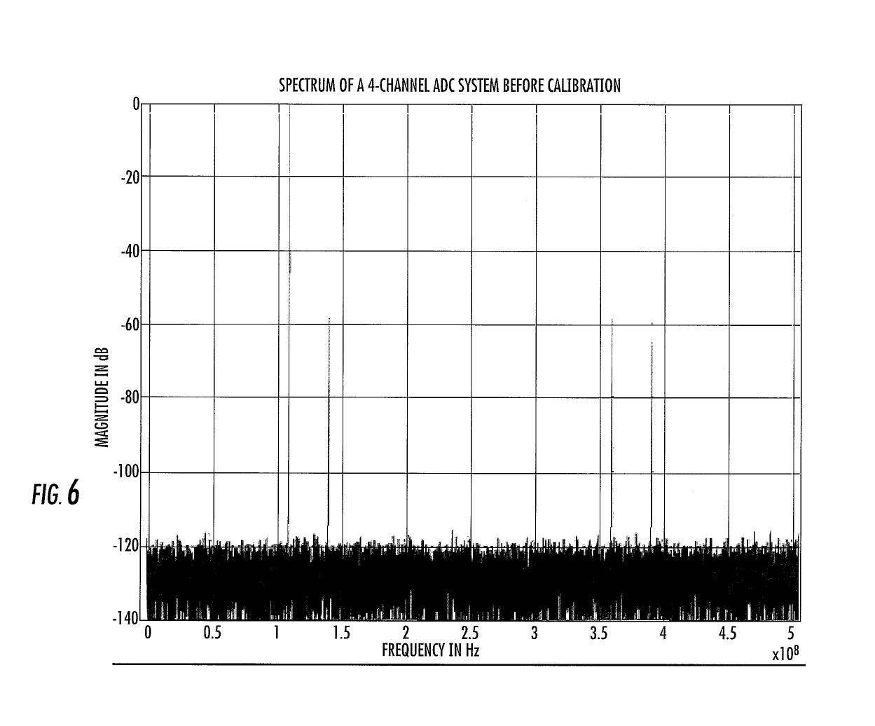

Gain differences in the ADCs 102-1, 102-2, . . . , 102-k, . . . , 102-M produce gain spurs at +Fᵢₙ+kF_{S}/M frequencies, where Fᵢₙ, is the set of input frequencies and k=1, 2, . . . , M. FIG. 6 shows the simulated spectrum of a simulated 110 MHz tone in a four-channel time-interleaved ADC sampling at 1 GHz where the gain spurs appear at 140 MHz, 360 MHz and 390 MHz. In order to minimize the amplitude of these spurs, the power of the signals from each ADC 102-1, 102-2, . . . , 102-k, . . . , 102-M must be determined and compared with that of the reference ADC. Again, as in the case of the offset mismatch estimation, the input to ADCₖ is also passed through ADCᵣ. The output from both these ADCs will be different due to differences in the gain of the two ADCs (ADCₖ and ADCᵣ). In the process of minimizing the difference in the gains between the different ADCs, we compare the gain of each ADCₖ with that of ADC, and use an adaptive algorithm to minimize the difference. In this way, all the ADCs will eventually be adjusted to have approximately the same gain.

Towards minimizing the difference in gains of all the ADCs, we define

$${Y}_{k} = \frac{1}{{N}_{g}} {\sum }_{n = 0}^{{N}_{g} - 1} {x}_{k}^{2} ( n ) \qquad ( 7 )$$

where xₖ(n) represents the samples from ADCₖ, N_{g} is the number of samples collected to obtain Yₖ, and k=1, 2, . . . M. Since the same input is passed through ADCᵣ, we define

$${Y}_{r} = \frac{1}{{N}_{g}} {\sum }_{n = 0}^{{N}_{g} - 1} {x}_{r}^{2} ( n ) \qquad ( 8 )$$

We now define a gain error for each ADCₖ as

Eₖ^{gain}=Yᵣ−Yₖ (9)

for k=1, 2, . . . M.

Below we outline an adaptive algorithm to correct the gain error in each ADCₖ based on Eₖ^{gain}, for k=1, 2, . . . M.

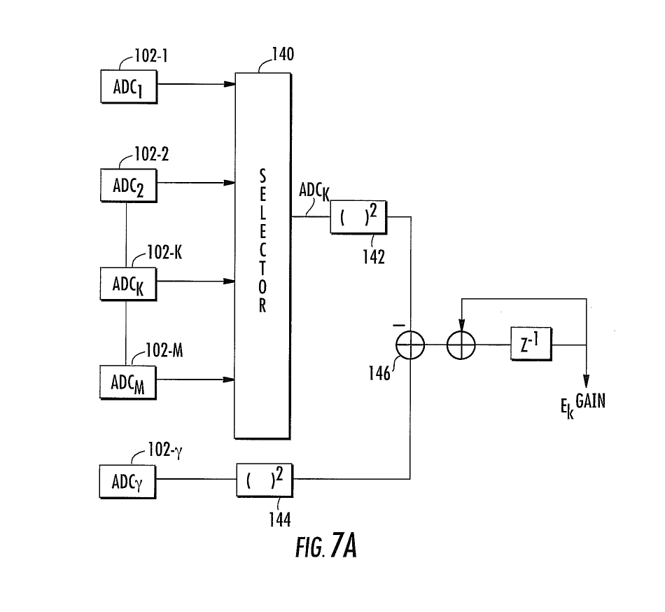

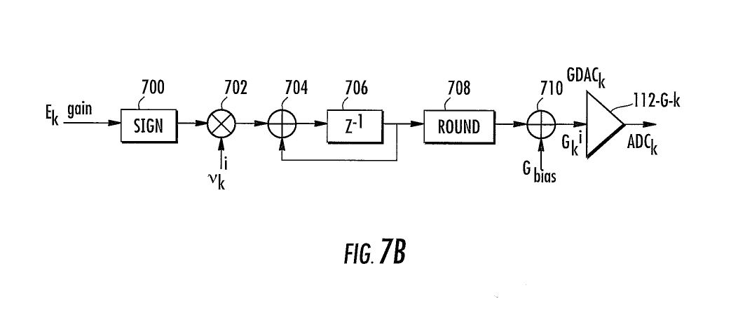

A flow diagram of one implementation to determine Eₖ^{gain} is shown in FIG. 7A. This implementation takes advantage of the fact that the difference of the sum of the squares as specified by equations (7)(8) and (9) can be determined by taking the squares first and then the difference. Selector 140 chooses one of the ADC outputs as ADCₖ which is then squared 142. The output of ADCₖ is then squared at 144. The difference of the squares is determined by subtractor 146 and then accumulated by summer 147 and delay 148. The accumulated output provides Eₖ^{gain}. As for the gain determination, the division by N_{g} is not necessary in this implementation since only the sign of the result is used for the correction.

Once the gain error has been determined, the next step is to determine an amount of the correction. Referring back to FIG. 2, let GDACₖ be the DAC 112-G-k that provides the gain correction to ADCₖ. Let R_{G} be the range of the GDACₖ. A step size that controls the convergence of the adaptive algorithm associated with gain correction is denoted by vₖⁱ for ADCₖ at the ith iteration. The value of vₖⁱ lies in the range [vₖ^{offsetmin}, vₖ^{offsetmax}]. Let Gₖⁱ be the value input to the GDACₖ. Again, the values of Gₖⁱ can vary between [−128, 127] or between [0, 255] if R_{G}=256. The constant G_{bias} is a value that allows the correction to be done with respect to a certain bias. For the case when G_{bias}=R_{G}/2=128, the input to the GDACₖ lies in the range [0, 255]. On the other hand, when the range of the GDACₖ input values is in [−128, 127], G_{bias}=0. Let βₖⁱ denote a variable that provides correction to the GDACₖ input Gₖⁱ associated with ADCₖ at the ith iteration. We can now write the adaptive algorithm for gain correction as

$$\begin{matrix}{G}_{k}^{i} = {G}_{bias} + round ( {β}_{k}^{i} ) & ( 10 ) \\ {β}_{k}^{i + 1} = {β}_{k}^{i} + sign ( {E}_{k}^{gain} ) {v}_{k}^{i} & ( 11 ) \\ {v}_{k}^{i + 1} = max ( \frac{{v}_{k}^{i}}{2} , {v}_{k}^{gainmin} ) for i = {s}_{k} & ( 12 )\end{matrix}$$

where βₖ⁰=0, vₖ⁰=vₖ^{gainmax}, and sₖ is any arbitrary positive number. The convergence can be controlled by vₖⁱ by changing its value at every sₖth iteration.

In FIG. 7B, a schematic for an adaptive algorithm to perform the gain correction is shown. The sign 700 of each Eₖ^{gain} is multiplied 702 by the adaptation step-size and accumulated 704, 706. The accumulated value in each iteration is rounded 708 to the nearest integer value and added 710 to the gain bias, G_{bias}, to provide the gain correction value to GDACₖ 112-G-k. The output of GDACₖ directly or indirectly controls the gain setting on the selected ADCₖ. The above adaptive process converges to an optimal value that minimizes the gain error in each ADCₖ.

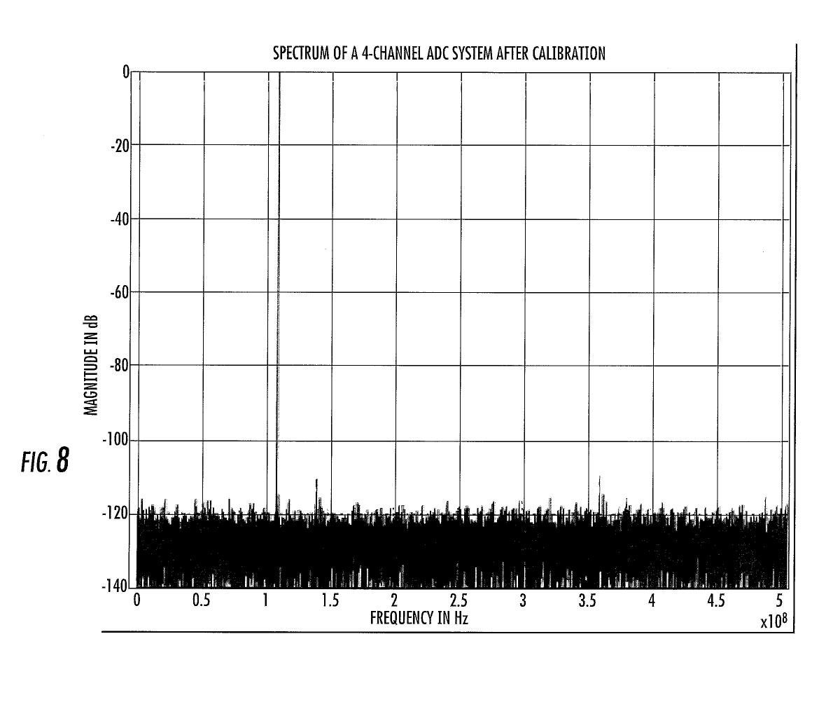

FIG. 8 shows the spectrum of the simulated tone mentioned in FIG. 6 after gain mismatch correction. As can be seen from the figure, the gain spurs at 140 MHz, 360 MHz and 390 MHz have been minimized. Just as in the simulation for offset mismatch estimation and correction, the wordlength of each ADCₖ is 14 bits while that of ADC, is 10 bits.

### Phase Correction

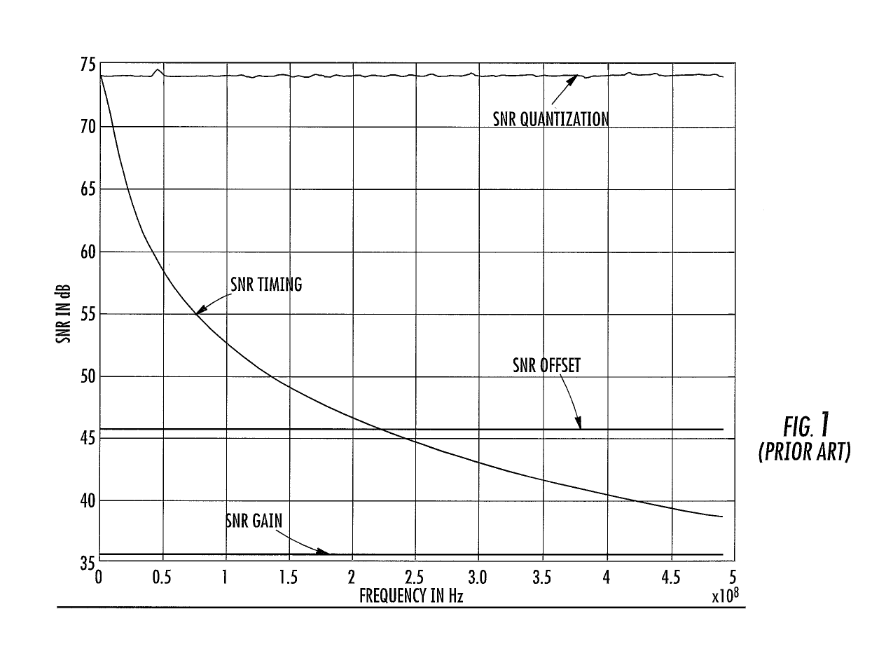

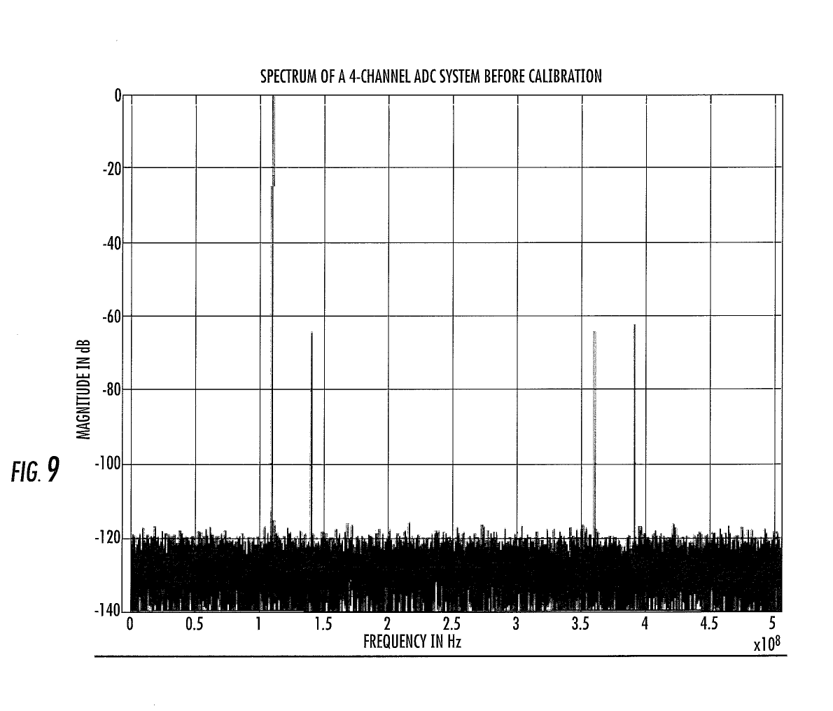

Since all the ADCs 102-1, 102-2, . . . , 102-k, . . . , 102-M do not have uniform sample instants in reference to the sampling frequency of the MCTIADC, timing or phase spurs show up at the same frequencies as those due to gain errors. The one difference is that gain spurs are orthogonal to the phase spurs. Additionally, as can be seen from FIG. 1, the spur is dependent on the frequency of the input signal. FIG. 9 shows the simulation spectrum of a 110 MHz tone in a four-channel time-interleaved ADC sampling at 1 GHz with phase spurs. As can be seen, the phase spurs occur at the same frequencies as those shown in FIG. 6. In order to minimize the amplitude of these spurs, the phase of each ADCₖ 102-1, 102-2, . . . , 102-k, . . . , 102-M is compared with the phase of ADCᵣ 102-r and the difference is minimized. As in the case of offset and gain, the input to a selected ADCₖ is also input to the reference ADC, i.e., ADCᵣ. The concept of minimizing the difference in the sample timings of these two ADCs will be explained below.

Let us define

$${Z}_{k} = \frac{1}{{N}_{p}} {\sum }_{n = 0}^{{N}_{p} - 1} {( {x}_{r} ( n ) - {x}_{k} ( n ) )}^{2} \qquad ( 13 )$$

where Nₚ is the number of samples collected to obtain the average Zₖ, and k=1, 2, . . . M. It is observed that the variation of Zₖ with phase follows a quadratic curve. Consequently, the minimum of Zₖ is obtained as the minimum of the quadratic curve. Towards this end, we define a phase error for ADCₖ as

$${E}_{k}^{phase} = \frac{1}{{N}_{p}} {\sum }_{n = 1}^{{N}_{p} - 1} ( {x}_{r} ( n ) - {x}_{k} ( n ) ) ( {x}_{k} ( n ) - {x}_{k} ( n - 1 ) ) \qquad ( 14 )$$

which is obtained by differentiating Zₖ from Eqn. (13).

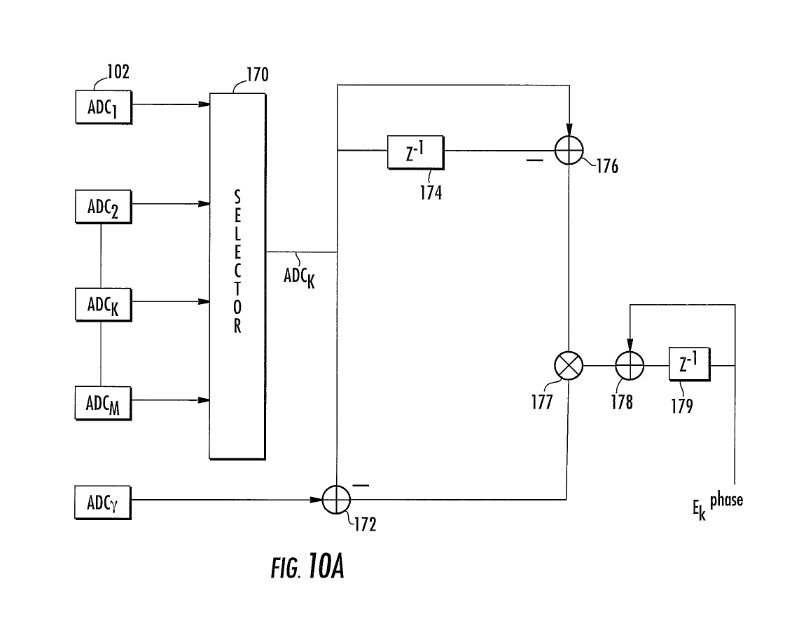

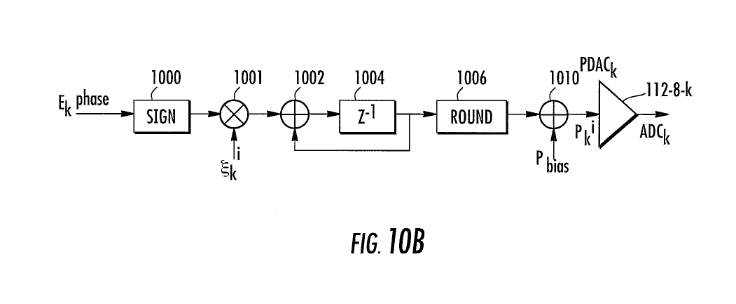

FIG. 10A is a flow diagram illustrating how the phase error can be determined in one implementation. The ADCₖ output by selector 170 is subtracted from ADCᵣ at 172. ADCₖ is also fed to delay 174 and subtractor 176. The outputs of subtractor 176 and difference 172 are multiplied by each other and then accumulated by summer 178 and delay 179. The result provides Eₖ^{phase}. As with the offset and gain error measurement, only the sign of the result will be used, so division by Nₚ is not necessary in the practical embodiment shown.

We now provide an adaptive algorithm to correct the phase error in each ADCₖ based on the determined Eₖ^{phase}, for k=1, 2, . . . M.

Let PDACₖ be the DAC 112-P-k that provides the timing or phase correction to ADCₖ. Let R_{P} be the range of the PDACₖ. A step size that controls the convergence of the adaptive algorithm associated with phase correction is denoted by ξₖⁱ for ADCₖ at the ith iteration. The value of ξₖⁱ is constrained to be in the range [ξₖ^{phasemin}, ξₖ^{phasemax}]. Let Pₖⁱ be the value input to the PDACₖ. The values of Pₖⁱ can vary between [−128, 127] or between [0, 255] if R_{P}=256. The constant P_{bias} is a value that allows the correction to be done with respect to a certain bias. For the case when P_{bias}=R_{P}/2=128, the input to the PDACₖ lies in the range [0, 255]. On the other hand, when the range of the PDACₖ input values is in [−128, 127], P_{bias}=0. Let γₖⁱ denote a variable that provides correction to the PDACₖ input Pₖⁱ associated with ADCₖ at the ith iteration. We can now write the adaptive algorithm for phase correction as

$$\begin{matrix}{P}_{k}^{i} = {P}_{bias} + round ( {γ}_{k}^{i} ) & ( 15 ) \\ {γ}_{k}^{i + 1} = {γ}_{k}^{i} + sign ( {E}_{k}^{phase} ) {ξ}_{k}^{i} & ( 16 ) \\ {ξ}_{k}^{i + 1} = max ( \frac{{ξ}_{k}^{i}}{2} , {ξ}_{k}^{phasemin} ) for i = {t}_{k} & ( 17 )\end{matrix}$$

where γₖ⁰=0, ξₖ⁰=ξₖ^{phasemax}, and tₖ is any arbitrary positive number. The convergence of the adaptive algorithm is controlled ξₖⁱ by changing its value at every tₖth iteration.

In FIG. 10B, a schematic for adaptive algorithm performing phase correction is shown. The sign 1000 of each Eₖ^{phase} is multiplied 1001 by the adaptation step-size and accumulated (1002, 1004). The accumulated value in each iteration is rounded 1006 to the nearest integer value and added 1010 to the phase bias, P_{bias}, to provide the phase correction value to PDACₖ 112-P-K. The output from PDACₖ directly or indirectly controls the phase setting on ADCₖ.

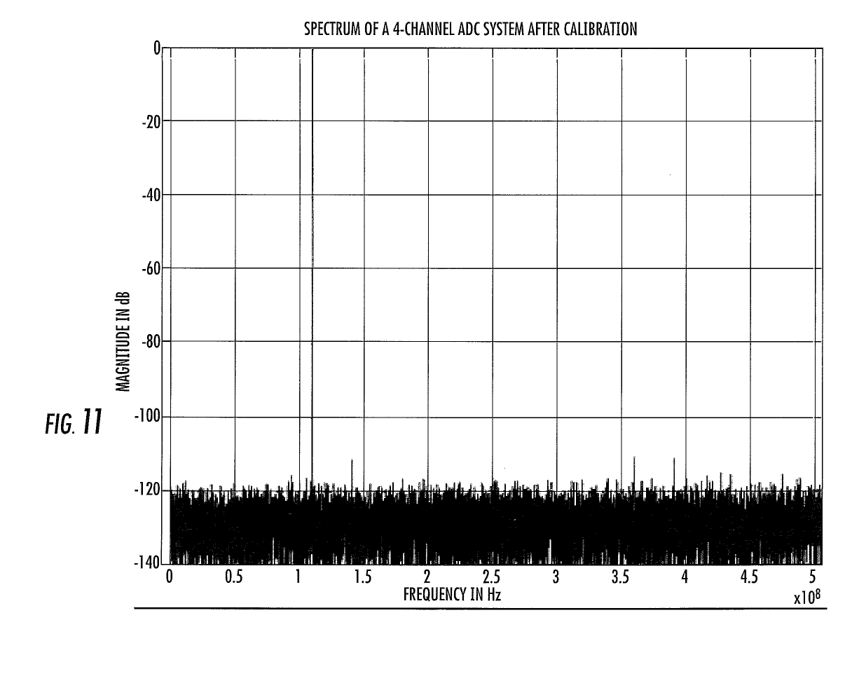

FIG. 11 shows the simulated spectrum of the tone mentioned in FIG. 9 after phase correction. As can be seen from the figure, the phase spurs at 140 MHz, 360 MHz and 390 MHz have been minimized. Again, the word length of each ADCₖ is 14 bits while that of ADCᵣ is 10 bits.

So far we have described the adaptive algorithms pertaining to specific mismatch errors. In the presence of all the mismatches, viz., offset, gain and phase mismatches, the adaptive algorithms are either run in a round-robin manner, starting with offset, then gain and then phase, for each ADCₖ or in a parallel fashion where all the mismatches are estimated and corrected simultaneously, or some sort of hybrid approach, where all of the adjustments for a given ADCₖ are determined and corrected simultaneously, or all m offsets, then gain, then phase are determined simultaneously, etc.

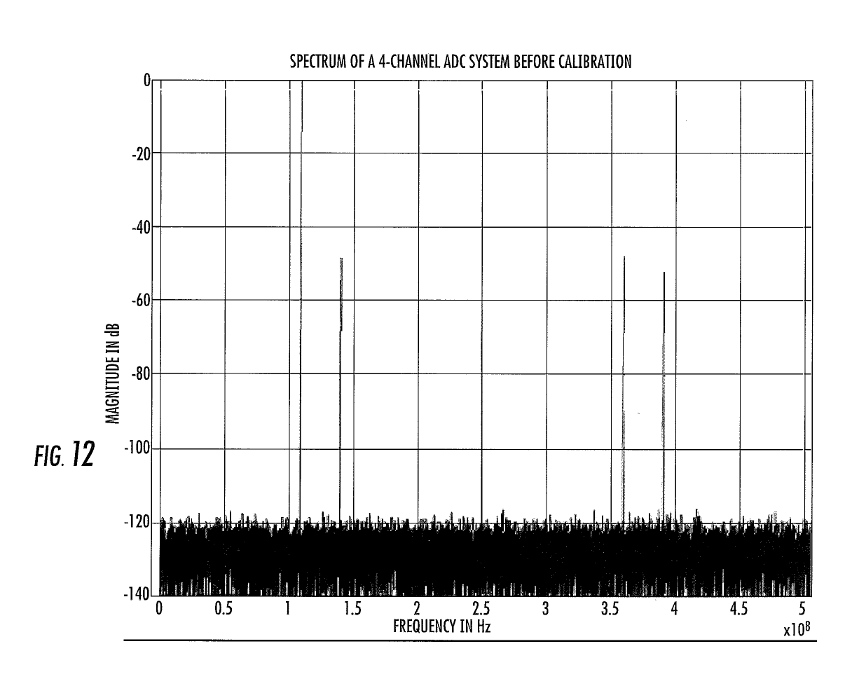

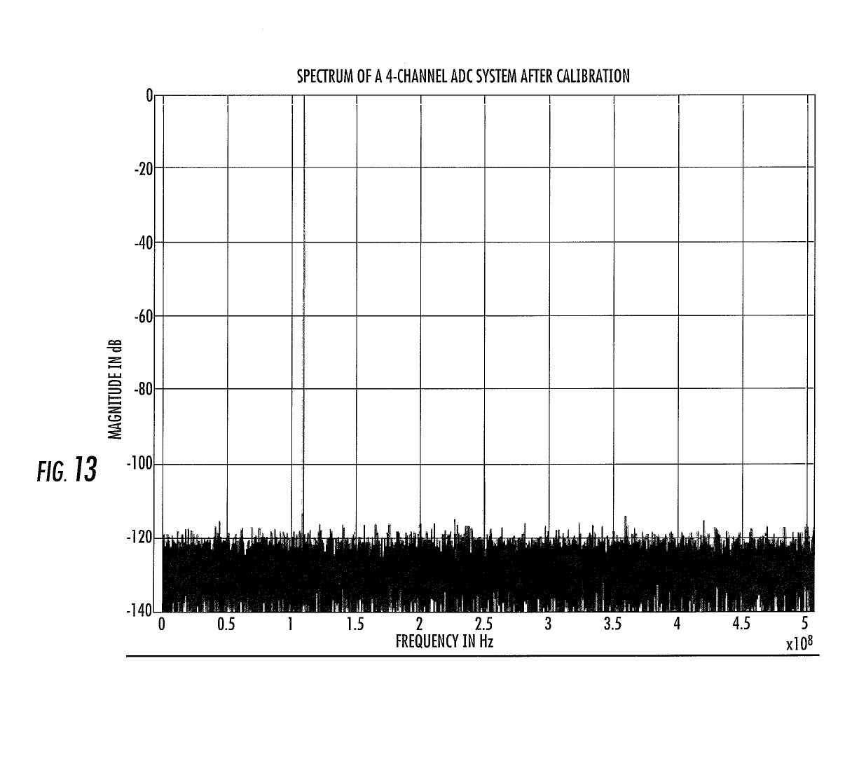

FIG. 12 shows the spectrum of a simulated tone with all the mismatch errors while FIG. 13 shows the spectrum after all mismatch errors have been minimized. As can be seen from the figure, the offset spurs at 250 MHz and 500 MHz, as well as gain and phase spurs at 140 MHz, 360 MHz and 390 MHz have been minimized.

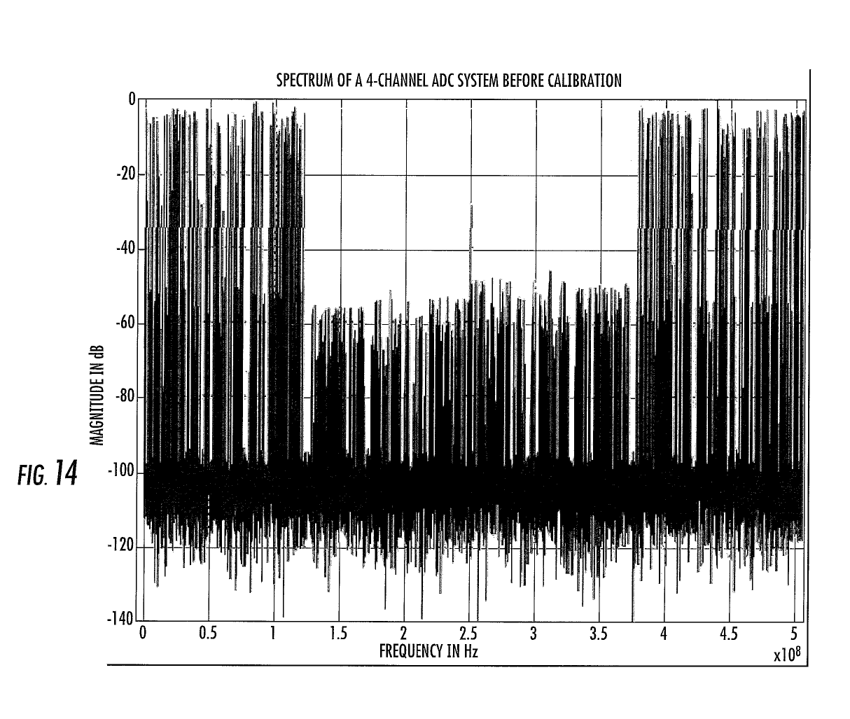

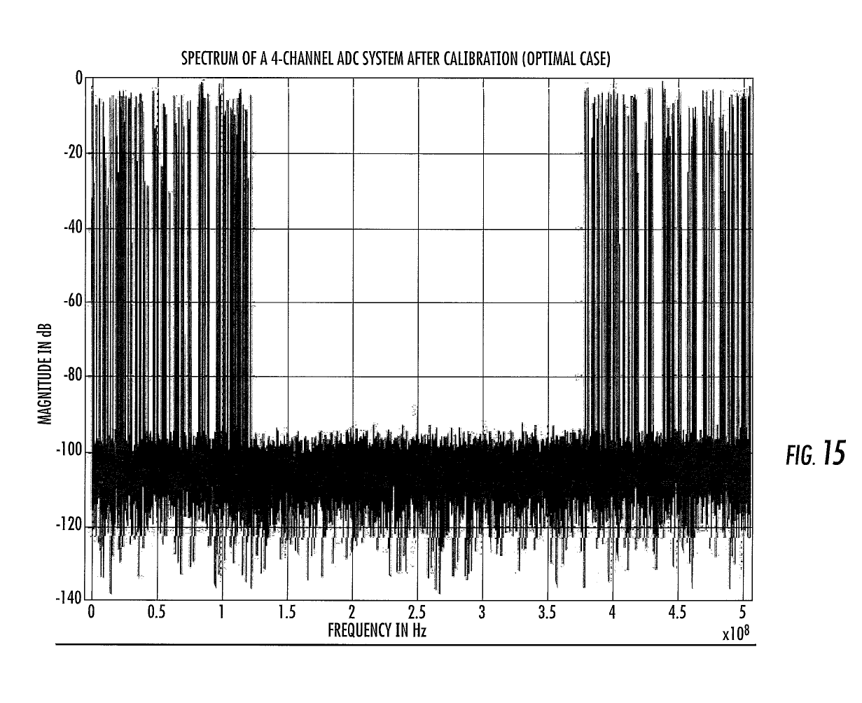

The adaptive algorithms described thus far have shown to work for the case when the input is a single tone. It can be shown that the same set of algorithms will work for the case when the input signal is a wide-band. FIG. 14 shows the spectrum of a simulated wide-band signal comprised of many sinusoids in presence of offset, gain and phase mismatch errors In this simulation, we have chosen a signal with 100 tones between zero and F_{S}/8 and another 100 tones between 3F_{S}/8 to F_{S}/2 so as to visualize the offset, gain and phase mismatch spurs populating the spectrum between F_{S}/8 to 3F_{S}/8. It can be seen from FIG. 15 that mismatch spurs have been significantly minimized.

High sample rate, time interleaved ADCs such as that described above can find application in many different types of systems. One such application is in a digital radio receiver. Such receivers have historically used analog tuner devices to demodulate a small portion of the input signal spectrum down to a low frequency. Relatively speaking, the tuner output has a low center frequency and low total bandwidth, thus allowing a low speed analog-to-digital converter to be used to digitize the data. Using high speed ADC systems 100, the total bandwidth can be increased while retaining the flexibility of digital systems.

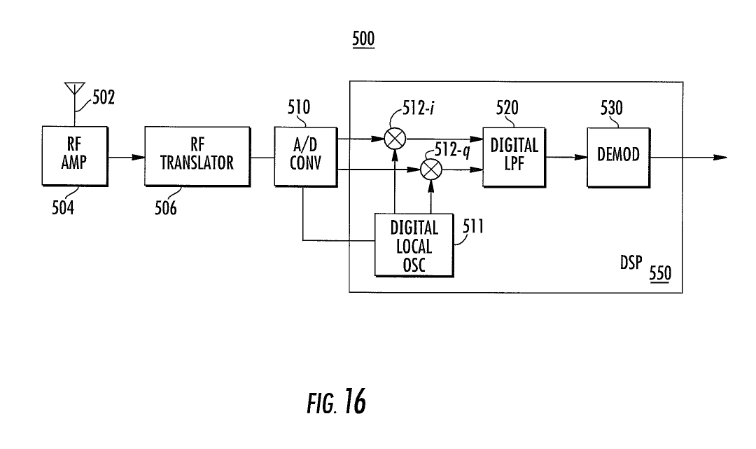

One particular use of the ADC system 100 is to implement a digital radio receiver as generally shown in FIG. 16. A radio frequency (RF) signal is fed to a radio frequency RF amplifier 504. In a wireless application, the RF signal may be received from an antenna 502; in other applications such as a cable modem, it may be received via a wire. The amplified RF signal is then fed to an RF translator 506 to down-convert the amplified RF signal to an intermediate frequency (IF). After the RF translator 506 (which may be optional) the ADC 510 (which may be implemented as the ADC system 100 described above) is then used to digitize the RF input into digital samples for subsequent processing. A digital local oscillator 511 may operate digital mixers 512-i and 512-q to provide for in phase and quadrature samples thereof. A digital low pass filter 520 limits the frequency content of resulting signal to the desired bandwidth. A demodulator 530 then recovers the original modulated signal from the same using. One or more of the operations of the digital local oscillator 511, mixers 512, low pass filter 520 and/or demodulator 530 may be implemented in a digital signal processor (DSP) 550. The recovered signal may then be further processed converted back to an analog baseband signal or the like, depending on the specific end use for the digital receiver.

While this invention has been particularly shown and described with references to example embodiments thereof, it will be understood by those skilled in the art that various changes in form and details may be made therein without departing from the scope of the invention encompassed by the appended claims.

What is claimed is:

1. An apparatus comprising:
a clock signal generator, for generating a plurality, M, of clock signals with at least some of clock signals having a different one of a selected plurality of clock phases offset by an amount determined by M;
a plurality, M, of Analog to Digital Converters (ADCs) coupled to the clock signal generator, the ADCs for converting an input signal to a set of ADC outputs as M digital values in response to a respective one of the M clock signals, each of the ADCs having at least one of an offset correction input, a gain correction input, or a phase correction input;
a multiplexer, for interleaving the M digital values output by the ADCs to form a digital representation of the input signal;
at least one reference ADC coupled to the clock signal generator and the is input signal, and to output a reference digital value in response to at least one of the M clock signals; and
an adaptive processor, for estimating at least one of an offset, gain or phase error in at least one of the ADCs, and generating one or more correction signals in response thereto by:
selecting at least one of the M digital values as a selected digital value;
comparing the selected digital value and the reference value to produce a comparison result;
determining an error estimate by accumulation of the comparison result over a predetermined number of samples of the selected digital value and the reference value;
from the error estimate, determining at least one of an offset, gain or phase correction value corresponding to one or more estimated correction signals; and
the estimated correction signals connected to at least a corresponding one of the offset, gain, or phase correction inputs of the ADCs.

2. The apparatus of claim 1 wherein the adaptive processor determines an offset error estimate from a difference between an average of the selected digital values and an average of the accumulated reference values.

3. The apparatus of claim 1 wherein the adaptive processor determines a gain error estimate from a difference of squares of the selected digital value and the reference value.

4. The apparatus of claim 1 wherein the adaptive processor determines a phase error estimate from a difference between the selected digital values and the reference values, as well as from a difference between two consecutive samples of the selected digital values, prior to the accumulation.

5. The apparatus of claim 1 additionally comprising:
one or more Digital to Analog Converters (DACs), connected to receive at least one of the offset, gain, or phase correction values, and to produce an analog correction signal to be applied to a selected one of the M ADCs.

6. The apparatus of claim 5 additionally comprising:
a plurality of DACs, with M of the DACs associated with each of an offset, gain, or phase correction input to each one of the M ADCs.

7. The apparatus of claim 1 wherein the adaptive processor further determines offset, gain, and phase corrections individually one at a time for each of the M ADCs, and a single reference ADC, ADCᵣ, provides the reference values for correcting one of the offset, gain, and phase for a given one, ADCₖ, of the M ADCs at a given time.

8. The apparatus of claim 1 wherein a plurality of reference ADCs provide two or more reference values to enable corrections of offset, gain, and phase for two or more of the M ADCs at a given time.

9. The apparatus of claim 1 wherein the adaptive processor corrects for offset error and further
determines an offset error for ADCₖ as
$${E}_{k}^{offset} = {X}_{r} - {X}_{k}$$
$$where$$
$${X}_{k} = \frac{1}{{N}_{o}} {\sum }_{n = 0}^{{N}_{o} - 1} {x}_{k} ( n )$$
$${X}_{r} = \frac{1}{{N}_{o}} {\sum }_{n = 0}^{{N}_{o} - 1} {x}_{r} ( n ) ;$$
and xₖ(n) are samples of the selected digital value from one of ADCₖ, xᵣ(n) are samples of the reference value from ADCᵣ, and Nₒ is a number of samples collected, for at least one value of k=1, 2, . . . M; and
determines a correction for offset from the offset error as
$${O}_{k}^{i} = {O}_{bias} + round ( {α}_{k}^{i} )$$
$$where$$
$${α}_{k}^{i + 1} = {α}_{k}^{i} + sign ( {E}_{k}^{offset} ) {μ}_{k}^{i}$$
$$and$$
$${μ}_{k}^{i + 1} = max ( \frac{{μ}_{k}^{i}}{2} , {μ}_{k}^{offsetmin} ) for i = {r}_{k}$$
and where O_{bias} is a constant that allows the correction to be done with respect to a certain bias, aₖⁱ is a variable the provides correction to the ODACₖ input Oₖⁱ, aₖ⁰=0, μₖ⁰=μₖ^{offsetmax}, and rₖ is any arbitrary positive number, and where convergence is controlled by changing a value of μₖⁱ at every rₖth iteration where μₖⁱ is constrained to be in the range [μₖ^{offsetmin}, μₖ^{offsetmax}].

10. The apparatus of claim 1 wherein the adaptive processor corrects for gain error and further
determines a gain error for each ADCₖ as
$${E}_{k}^{gain} = {Y}_{r} - {Y}_{k} ;$$
$$where$$
$${Y}_{k} = \frac{1}{{N}_{g}} {\sum }_{n = 0}^{{N}_{g} - 1} {x}_{k}^{2} ( n )$$
$$and$$
$${Y}_{r} = \frac{1}{{N}_{g}} {\sum }_{n = 0}^{{N}_{g} - 1} {x}_{r}^{2} ( n ) ;$$
and xₖ(n) are samples of the selected digital value from one of ADCₖ, xᵣ(n) are samples of the reference value from ADCᵣ, and N_{g} is a number of samples collected, for at least one value of k=1, 2, . . . M; and
determines a gain correction from the gain error as
$${G}_{k}^{i} = {G}_{bias} + round ( {β}_{k}^{i} )$$
$$where$$
$${β}_{k}^{i + 1} = {β}_{k}^{i} + sign ( {E}_{k}^{gain} ) {v}_{k}^{i}$$
$$and$$
$${v}_{k}^{i + 1} = max ( \frac{{v}_{k}^{i}}{2} , {v}_{k}^{gainmin} ) for i = {s}_{k}$$
and where G_{bias} is a constant that allows the correction to be done with respect to a certain bias, βₖⁱ is a variable the provides correction to the GDACₖ input Gₖⁱ, βₖ⁰=0, vₖ⁰=vₖ^{gainmax}, and sₖ is any arbitrary positive number, and where convergence is controlled by changing a value of vₖⁱ at every sₖth iteration where vₖⁱ is constrained to be in the range [vₖ^{offsetmin}, vₖ^{offsetmax}].

11. The apparatus of claim 1 wherein the adaptive processor corrects for phase error and further
determines a phase error for ADCₖ as
$${E}_{k}^{phase} = \frac{1}{{N}_{p}} {\sum }_{n = 1}^{{N}_{p} - 1} ( {x}_{r} ( n ) - {x}_{k} ( n ) ) ( {x}_{k} ( n ) - {x}_{k} ( n - 1 ) )$$
where xₖ(n) are samples of the selected digital value output from one of ADCₖ, xᵣ(n) are samples of the reference value from ADCᵣ, and N_{P} is a number of samples collected, for at least one value of k=1, 2, . . . M; and
determines a correction for phase error as
$${P}_{k}^{i} = {P}_{bias} + round ( {γ}_{k}^{i} )$$
$$where$$
$${γ}_{k}^{i + 1} = {γ}_{k}^{i} + sign ( {E}_{k}^{phase} ) {ξ}_{k}^{i}$$
$${ξ}_{k}^{i + 1} = max ( \frac{{ξ}_{k}^{i}}{2} , {ξ}_{k}^{phasemin} ) for i = {t}_{k}$$
and where P_{bias} is a constant that allows the correction to be done with respect to a certain bias, γₖⁱ is a variable the provides correction to the PDACₖ input Pₖⁱ, γₖ⁰=0, ξₖ⁰=ξₖ^{phasemax}, and tₖ is any arbitrary positive number, and where convergence is controlled by changing a value of ξₖⁱ at every tₖth iteration where ξₖⁱ is constrained to be in the range [ξₖ^{phasemin}, ξₖ^{phasemax}].

12. The apparatus of claim 1 implemented in a receiver for a communication system.

13. A method comprising:
generating a plurality, M, of clock signals, with at least some of clock signals having a different one of a selected plurality of clock phases, where a is phase difference between selected clock phases depends on a value of M;
converting an input signal with a plurality, M, of Analog to Digital Converters (ADCs) coupled to the M clock signals, to provide to a set of ADC outputs as M digital signals, each of the ADCs having at least one of an offset correction input, a gain correction input, or a phase correction input;
interleaving the M digital values output by the ADCs to form a digital representation of the input signal;
converting the input signal with a reference ADC to output reference digital values in response to at least one of the M clock signals; and
estimating one or more correction signals for at least one of offset, gain, and phase error in at least one of the ADCs by:
determining a set of selected digital values from one of the M digital signals over a predetermined number of ADC output samples;
determining a set of reference values over a predetermined number of ADC output samples;
comparing the set of selected digital values and the set of reference values, to produce a comparison result;
accumulating the comparison result to provide an error estimate; and
from the error estimate, determining at least one of an offset, gain or phase correction corresponding to one or more correction signals to be applied to correct at least one of offset, gain, or phase error of at least one of the ADCs.

14. The method of claim 13 further comprising:
estimating an offset error from a difference between an average of the accumulated digital values and an average of the accumulated reference values.

15. The method of claim 13 further comprising:
estimating a gain error from a difference of squares of a digital value and at least one reference value.

16. The method of claim 13 further comprising:
estimating a phase error from a difference between the digital values and the reference values as well as from a difference between two consecutive samples of the selected digital values.

17. The method of claim 13 additionally comprising:
Digital to Analog Converting at least one of the offset, gain, or phase correction values to provide an analog correction signal, and
providing the corresponding analog correction signal to a selected one of the correction inputs of the ADCs.

18. The method of claim 17 additionally comprising:
providing a plurality of offset, gain, or phase correction input to each one of the correction inputs of the M ADCs.

19. The method of claim 13 additionally comprising:
individually determining offset, gain, and phase corrections for each of the ADCs using a single reference ADC, ADCᵣ, to determine a signal to be fed to one of the offset, gain, or phase correction input of a given one, ADCₖ, of the ADCs at a given instant in time.

20. The method of claim 13 additionally comprising:
providing a plurality of reference signals to two or more offset, gain, and phase correction inputs of two or more of the ADCs at a given time.

21. The method of claim 13 additionally comprising correcting for offset error by:
determining an offset error for ADCₖ as
$${E}_{k}^{offset} = {X}_{r} - {X}_{k}$$
$$where$$
$${X}_{k} = \frac{1}{{N}_{o}} {\sum }_{n = 0}^{{N}_{o} - 1} {x}_{k} ( n )$$
$${X}_{r} = \frac{1}{{N}_{o}} {\sum }_{n = 0}^{{N}_{o} - 1} {x}_{r} ( n ) ;$$
and xₖ(n) are samples of the selected digital value from one of ADCₖ, xᵣ(n) are samples of the reference value from ADCᵣ, and Nₒ is a number of samples collected, for at least one value of k=1, 2, . . . M; and
determines a correction for offset from the offset error as
$${O}_{k}^{i} = {O}_{bias} + round ( {α}_{k}^{i} )$$
$$where$$
$${α}_{k}^{i + 1} = {α}_{k}^{i} + sign ( {E}_{k}^{offset} ) {μ}_{k}^{i}$$
$$and$$
$${μ}_{k}^{i + 1} = max ( \frac{{μ}_{k}^{i}}{2} , {μ}_{k}^{offsetmin} ) for i = {r}_{k}$$
and where O_{bias} is a constant that allows the correction to be done with respect to a certain bias, aₖⁱ is a variable the provides correction to the ODACₖ input Oₖⁱ, aₖ⁰=0, μₖ⁰=μₖ^{offsetmax}, and rₖ is any arbitrary positive number, and where convergence is controlled by changing a value of μₖⁱ at every rₖth iteration where μₖⁱ is constrained to be in the range [μₖ^{offsetmin}, μₖ^{offsetmax}].

22. The method of claim 13 additionally comprising correcting for gain error by:
determining a gain error for each ADCₖ as
$${E}_{k}^{gain} = {Y}_{r} - {Y}_{k} ;$$
$$where$$
$${Y}_{k} = \frac{1}{{N}_{g}} {\sum }_{n = 0}^{{N}_{g} - 1} {x}_{k}^{2} ( n )$$
$$and$$
$${Y}_{r} = \frac{1}{{N}_{g}} {\sum }_{n = 0}^{{N}_{g} - 1} {x}_{r}^{2} ( n ) ;$$
and xₖ(n) are samples of the selected digital value from one of ADCₖ, xᵣ(n) are samples of the reference value from ADCᵣ, and N_{g} is a number of samples collected, for at least one value of k=1, 2, . . . M; and
determines a gain correction from the gain error as
$${G}_{k}^{i} = {G}_{bias} + round ( {β}_{k}^{i} )$$
$$where$$
$${β}_{k}^{i + 1} = {β}_{k}^{i} + sign ( {E}_{k}^{gain} ) {v}_{k}^{i}$$
$$and$$
$${v}_{k}^{i + 1} = max ( \frac{{v}_{k}^{i}}{2} , {v}_{k}^{gainmin} ) for i = {s}_{k}$$
and where G_{bias} is a constant that allows the correction to be done with respect to a certain bias, βₖⁱ is a variable the provides correction to the GDACₖ input Gₖⁱ, βₖ⁰=0, vₖ⁰=vₖ^{gainmax}, and sₖ is any arbitrary positive number, and where convergence is controlled by changing a value of vₖⁱ at every sₖth iteration where vₖⁱ is constrained to be in the range [vₖ^{offsetmin}, vₖ^{offsetmax}].

23. The method of claim 13 additionally comprising correcting for phase error by:
determining a phase error for ADCₖ as
$${E}_{k}^{phase} = \frac{1}{{N}_{p}} {\sum }_{n = 1}^{{N}_{p} - 1} ( {x}_{r} ( n ) - {x}_{k} ( n ) ) ( {x}_{k} ( n ) - {x}_{k} ( n - 1 ) )$$
where xₖ(n) are samples of the selected digital value output from one of ADCₖ, Xᵣ(n) are samples of the reference value from ADCᵣ, and N_{P} is a number of samples collected, for at least one value of k=1, 2, . . . M; and
determines a correction for phase error as
$${P}_{k}^{i} = {P}_{bias} + round ( {γ}_{k}^{i} )$$
$$where$$
$${γ}_{k}^{i + 1} = {γ}_{k}^{i} + sign ( {E}_{k}^{phase} ) {ξ}_{k}^{i}$$
$${ξ}_{k}^{i + 1} = max ( \frac{{ξ}_{k}^{i}}{2} , {ξ}_{k}^{phasemin} ) for i = {t}_{k}$$
and where P_{bias} is a constant that allows the correction to be done with respect to a certain bias, γₖⁱ is a variable the provides correction to the PDACₖ input Pₖⁱ, γₖ⁰=0, ξₖ⁰=ξₖ^{phasemax}, and tₖ is any arbitrary positive number, and where convergence is controlled by changing a value of ξₖⁱ at every tₖth iteration where ξₖⁱ is constrained to be in the range [ξₖ^{phasemin}, ξₖ^{phasemax}].

24. The method of claim 13 used as part of a communication signal receiving process.

25. A system comprising:
a radio frequency amplifier, for receiving an input radio frequency signal;
a translator, for down converting the input radio frequency signal to a received signal;
an M-channel time-interleaved analog to digital converter (MCTIADC) connected to the received signal and to provide a digitized received signal, the MCTIADC further comprising:
a plurality, M, of Analog to Digital Converters (ADCs) for converting the received signal to a set of ADC outputs as M digital values, each of the ADCs having at least one of an offset correction input, a gain correction input, or a phase correction input;
a multiplexer, for interleaving the M digital values output by the ADCs to provide the digitized received signal;
at least one reference ADC coupled to the received signal, and to output a reference digital value; and
an adaptive processor, for estimating at least one of an offset, gain or phase error in at least one of the ADCs from the set of ADC outputs and the reference digital value, and generating one or more correction signals to be applied to one of the offset, gain, or phase correction inputs of at least one of the ADCs; and
a digital demodulator, connected to the digitized received signal, and to provide a digital demodulated signal.
